(19) United States
(12) Patent Application Publication
(10) Pub. No.: US 2006/0249372 A1
(43) Pub. Date: Nov. 9, 2006

(54) Biased target ion bean deposition (BTIBD) for the production of combinatorial materials libraries

(75) Inventors: Xiao Dong Xiang, Danville, CA (US); Qizhen Xue, Walnut Creek, CA (US); Young Yoo, Walnut Creek, CA (US)

Correspondence Address: QUINE INTELLECTUAL PROPERTY LAW GROUP, P.C., P O BOX 458, ALAMEDA, CA, 94501, US

(73) Assignee: Intematix Corporation, Moraga, CA (US)

(21) Appl. No.: 11/402,251

(22) Filed: Apr. 10, 2006

Related U.S. Application Data
(60) Provisional application No. 60/670,342, filed on Apr. 11, 2005.

(51) Int. Cl. C23C 14/00

(52) U.S. Cl. 204/192.11; 204/298.04

(57) ABSTRACT

This invention provides gradient deposition methods and systems to form libraries of combinatorial materials. The systems can include a shutter movable between alternate orientations around a substrate for deposition of gradients in different directions. Methods can include deposition of a gradient from targets illuminated by controlling target bias voltage onto a substrate past a mask or shutter movable to desired orientation coordinates.

### CROSS-REFERENCE TO RELATED APPLICATIONS

This application claims priority to and benefit of a prior U.S. Provisional Application No. 60/670,342, Biased Target Ion Beam Deposition (BTIBD) for the Production of Combinatorial Materials Libraries, by Xiao Dong Xiang, et al., filed Apr. 11, 2005. The full disclosure of the prior application is incorporated herein by reference.

### FIELD OF THE INVENTION

The present invention generally relates to methods and systems for deposition of materials onto substrates for the formation of materials gradients and combinatorial material arrays. The invention provides masks and movable shutters to efficiently and reproducibly deposit gradients on substrates. The gradient and array products can be useful in screening materials and material combinations for characteristics applicable, e.g., in semiconductor technology, superconductor technology, optical filters, and the like.

### BACKGROUND OF THE INVENTION

Ion beam deposition of materials onto substrates has been practiced to provide new materials and research tools in the fields of materials sciences, electronics, magnetism, electrokinetics, optics, imaging, and the like. Technologies exist to prepare combinatorial libraries of deposited materials. However, a need remains for systems with simplified target illumination and capabilities to easily form multiple gradients of materials on substrates in any orientation.

In Combinatorial Synthesis of Novel Materials, U.S. Pat. No. 5,985,356, to Shultz, et al., eight ion beam guns are each paired a target. Masks establish a shadow of target material that falls on a substrate. An discrete array of target material combinations is produced by a series of patterned depositions onto the substrate through patterned holes in the masks. The arrays produced are, e.g., 28 unique combinations of eight different materials in a discrete X-Y matrix array. Shultz does not provide, however, a way to make a continuous array (a gradient) or to deposit different materials at the same time. Therefore, the number of array combinations is limited and many steps are required to prepare an array.

Wu, et al., U.S. Pat. No. 6,045,671, provides a complex apparatus that allows robotic selection of target/mask/substrate combinations. Around a deposition chamber are storage areas for multiple targets, masks and substrates that can be moved to positions in the chamber to take part in a deposition. For example, a robotic actuator can slide a substrate onto a deposition stage, another robotic actuator can slide a desired target into the path of an ion beam, and another robotic actuator can place a desired mask between the substrate and the target. Illumination of the selected target causes material to be sputtered onto the substrate in a pattern dictated by the mask. After a first deposition is complete, another target and mask can be positioned in the chamber and different target material can be sputtered onto the substrate in a different pattern. Through a series of depositions and mask changes, a combinatorial library of sputtered material combinations can be produced on the substrate. Wu also discusses X and Y shutter pairs that can mask off the substrate leaving rectangular holes for deposition onto the substrate. The shutters can move across the substrate during deposition to form gradients of deposited material. New gradient orientations are not facilitated. For all its mechanical complexity, the Wu deposition system can deposit only one material at a time, with several mechanical steps to change targets. The substrate can not be rotated during deposition without losing register between the shutter and substrate.

A target voltage biasing scheme in Baldwin, U.S. Pat. No. 6,679,976, allows two or more targets to be illuminated with controlled sputter proportions at the same time from a single ion source. Baldwin directs relatively low energy ions or plasma from an ion source into the deposition chamber. Voltages applied to a target control the energy and number of ions that impact the target. The proportion of materials sputtered from two or more targets can thus be controlled by the relative biasing voltages of the targets. The Baldwin system can deposit layers in a gradient through the thickness of deposited material, but not gradients across the deposition surface to produce continuously variable combinatorial arrays. Baldwin can not form multiple gradients across a substrate.

In view of the above, a need exists for a deposition system that allows generation of multiple gradients of mixed materials. There can be benefits from systems that allow deposition of uniform layers while still allowing continuous gradient formation. It would be desirable to have a deposition system that can proportionately sputter material from two or more targets at once and provide for ready changes in gradient orientation. The present invention provides these and other features that will be apparent upon review of the following.

### SUMMARY OF THE INVENTION

The present invention includes methods and systems for deposition of materials gradients onto a substrate. Deposition systems include, e.g., a shutter that changes orientation to establish gradients from multiple desired directions across a substrate. The systems can illuminate targets for sputtering material under the control of target bias voltage. Shutters can be mounted along with substrates on a rotation assembly to allow gradient formation while the substrate is spun for deposition uniformity. Gradient deposition methods include, e.g., depositing a first gradient oriented by a shutter motion and moving the shutter to a new starting position relative to the substrate before depositing a second gradient oriented by motion of the shutter. Some methods include, e.g., rotating the shutter together with the substrate during deposition, or depositing gradients while selection of targets or target material proportions are controlled by target bias voltages.

An exemplary system for depositing gradients of materials onto a substrate can include targets, ion sources, shutter devices and substrates functionally mounted in a deposition chamber. The ion sources can be directed to illuminate one or more of the targets with ions to sputter materials from the targets. The sputtered materials can be deposited onto the substrate deposition surface in a gradient established by a blocking motion of a shutter. The shutter can be mounted to a shutter device capable of an orientation motion to any of a variety of desired orientation coordinates around an axis normal to the deposition surface to establish new orientations for blocking motions and gradient formation across the deposition surface. With the shutter device at a first orientation coordinate, the blocking motion of the shutter across the deposition surface during material sputtering can establish a first gradient of deposited materials on the deposition surface in a first orientation. Movement of the shutter device to a second orientation coordinate followed by blocking motion of the shutter across the deposition surface from the new location during material sputtering can establish a second gradient of deposited materials on the substrate in a second orientation.

Combined control of target biasing and shutter device orientation can provide multiple gradients of material with different proportions of material components. For example, the deposition system can include targets in electrical contact with a controllable target bias voltages and an ion source configured to selectively illuminate one or more of the targets with ions under the influence of the target bias voltages. Materials can be selectively sputtering from the one or more targets onto a substrate deposition surface past a shutter moving in a blocking motion that establishes the orientation of the first gradient of materials. The shutter device, or a mask, are moved in an orientation motion between positions around an axis normal to the deposition surface to new orientation coordinates to reset mask shadow alignments or shutter blocking motions establishing the orientation of a second gradient of deposited material gradients on the deposition surface. The second targets can be selected my merely changing target voltage biases. Multiple gradients of multiple materials at multiple orientations can be accomplished, e.g., without opening the deposition chamber.

Other embodiments of the systems optionally include a substrate and a shutter device that rotate together during depositions of materials. Such a system can include ion sources directed to illuminate targets with ions to sputter materials. A substrate can be mounted to rotate with one or more masks or shutter devices, e.g., on a common rotation assembly, so that the mask or shutter remains at the same an orientation coordinate relative to the substrate deposition surface while the substrate rotates. In this way, the orientation of a shutter blocking motion across and relative to the deposition surface can be maintained when the substrate is rotated, and/or the orientation of a mask shadow on the deposition surface can be maintained when the substrate is rotated. Optionally the substrate and mask or shutter device can rotate together while driven with separate rotation assemblies and/or shuttle mechanisms. Maintenance of the orientation coordinate allows the mask of shutter motion to control orientation of a gradient while the substrate is rotated in the flux sputtered material.

An exemplary method of depositing gradients of materials onto a substrate can include illuminating one or more first targets with ions from an ion source, thus sputtering materials from the targets. A first gradient of the first sputtered materials will be deposited in an orientation determined by moving a shutter in a first blocking motion across a deposition surface of the substrate. Moving a shutter device, on which the shutter is mounted, in an orientation motion to a second orientation coordinate around an axis normal to the deposition surface establishes an orientation for a second gradient deposition. Illuminating one or more second targets with ions and moving the shutter in a second blocking motion across the deposition surface of the substrate deposits a second gradient of the second sputtered material in an new orientation determined by the second blocking motion from the second orientation coordinate.

In many methods of the invention, illumination is controlled by controlling a target bias voltage. For example, depositing gradients of materials onto a substrate can be accomplished by controlling target bias voltages in contact with one or more targets to influence the illumination of the targets with ions from an ion source to sputter first materials. Blocking a portion of the first sputtered materials from deposition onto a substrate deposition surface with a mask or shutter device at a first orientation coordinate around an axis normal to the deposition surface can effect the depositing of a first gradient onto the deposition surface in a first orientation. Moving the substrate (while the shutter or mask remains in place) or moving the mask or shutter device relative to the substrate can change the orientation coordinate of the mask or shutter device to a second orientation coordinate. Illuminating one or more second targets can sputter second materials while the mask or shutter block deposition of a portion of the second sputtered materials onto the substrate deposition surface, thereby depositing a second gradient of the second materials onto the deposition surface in a second orientation. In alternative embodiments, selective illumination can be accomplished by selective activation of ion sources each directed at a different target.

In the methods, the substrate and shutters can be rotated together while the orientation coordinate is maintained. Depositing gradients materials onto a substrate with commonly rotating substrate and shutter can be accomplished by illuminating targets with ions from one or more ion sources to sputter materials from the one or more targets, rotating a substrate along with a shutter device having a shutter so that the shutter device is maintained at an orientation coordinate around an axis normal to a deposition surface of the substrate, moving the shutter in a blocking motion across the deposition surface of the substrate, and depositing the sputtered materials onto the deposition surface. A first gradient can thereby be deposited in an orientation established according to the blocking motion of the shutter relative to the deposition surface. After moving the shutter device to a different orientation coordinate, sputtered material can be deposited in a gradient having different orientation by moving the shutter in the blocking motion from the new coordinate while materials are sputtered.

A radial gradient of material can be deposited onto the substrate surface, e.g., by spinning the substrate on a rotation assembly while the shutter is moved in a blocking motion across between the surface and one or more target. For example, if a target is illuminated to sputter material while the substrate is spinning and a shutter is moving across the substrate surface, a radial gradient of the sputtered material can form, e.g., with a higher concentration or thicker deposition of the material in the center of the spinning axis and a lower concentration or thinner deposition of sputtered material on the surface away from the axis. The process can be repeated to provide multiple layers, e.g., with the same or different materials. The radial gradient can have changing composition, e.g., by illuminating two or more targets with changing intensity during the deposition.

A blocking motion across a deposition surface while changing the proportions of material sputtered from two or more targets can result in a gradient of material across the surface with changing proportions of materials. Such a method can include, e.g., sputtering materials from two or more targets in proportions that change with time, and moving the shutter across a substrate to progressively block deposition of the sputtered materials to form a gradient of materials which change in proportion across the substrate surface (and through the thickness of the material gradient). Multiple gradients with changing material proportions on the same substrate can be formed by deposition through a moving mask (e.g., a sheet with a slit, or using X-Y shutter pairs). The multiple gradients can have different radial orientations or be deposited in parallel rows or columns.

In the systems and methods, illumination of the targets with ions can be from one or more ion sources. The ions can be directed to illuminate the targets by mechanical or electronic direction of a beam from the ion source. Illumination can be controlled by independently controlling target bias voltages in contact with each of two or more of the targets. Two or more targets can be illuminated sequentially or at the same time from one ion source by controlling the bias voltages of the targets. Ion sources can be paired with targets so that selective activation of ion sources can control what target is illuminated at what time. The “ion source” of can emit any particles useful in ejecting material from a target surface, e.g., positive ions, negative ions, electrons, photons, and/or the like. In a typical embodiment, the ion source produces positive ions to illuminate targets.

The substrate can be mounted to a rotation assembly. Rotation of a substrate during deposition can provide, e.g., material deposition more uniform in thickness and more uniform in proportions when materials are sputtered from multiple targets. By mounting a shutter device to the same rotation assembly, orientation coordinates of the shutter device can be retained while the substrate rotates.

The character of the shutter blocking motion can affect the gradient profile of material deposited during the motion. For example, with constant rates of material sputtering, the rate of change of material thickness across the deposition surface can be, e.g., inversely proportional to the speed at which the shutter moves across the surface. Shutter blocking motion can be described by mathematical formulas that are ultimately reflected in the profile of material deposited during the shutter motion. In an aspect of the invention, the shutter can move across the deposition surface with, e.g., a constant velocity, a geometric change in velocity, stepped motion, a logarithmic change in velocity, a sigmoidal change in velocity, an orbital motion, and the like.

Masks can be positioned between the targets and deposition surfaces to change the pattern of material deposition. The masks can be sheets of material essentially impermeable to the flow of sputtered material and having holes that allow sputtered material to pass through. The holes can have patterns that result in desired gradient profiles. The size and distribution of the holes in the masks can be calculated to provide a desired gradient profile or can be determined empirically.

Gradients can be deposited onto a substrate in a variety of desirable orientations and/or combinations of materials. A single gradient can be formed with a selected orientation and composition. Two gradients can be deposited from the same or different materials in the same or different orientation. Two gradients deposited with opposite orientations (e.g., 180° relative orientations) can overlap to provide a level deposition surface, e.g., with wedge shaped gradient profiles pointed in opposite directions. Three or more gradients can be arranged, e.g., uniformly about radials centered on the substrate deposition surface, or can be oriented randomly. Formation of multiple gradients on a deposition surface is facilitated by the methods and systems described herein. Deposition of 1 or more, 2, 3, 4, 5, 6, 10, 100, 1000 or more, gradients onto a deposition surface, from any number of materials at any number of orientations, overlapping or not, is envisioned. Such a deposition surface can present from 1 to 1000, or more different material combinations for each gradient. Combinatorial libraries produced by the methods or systems of the invention can include from two to 10⁶, or more, different combinations of materials.

Targets used in the systems and methods can have a surface of material components releasable by illumination with an ion source. The materials typically presented for sputtering from the surface of a target include, e.g., Aluminum, Antimony, Barium, Bismuth, Boron, Cadmium, Calcium, Carbon, Cerium, Chromium, Cobalt, Copper, Dysprosium, Erbium, Europium, Gadolinium, Germanium, Gold, Hafnium, Holmium, Indium, Iridium, Iron, Lanthanum, Lead, Lithium, Lutetium, Niobate, Magnesium, Manganese, Molybdenum, Neodymium, Nickel, Niobium, Palladium, Permalloy, Platinum, Polonium, Praseodymium, Rhenium, Rhodium, Ruthenium, Samarium, Scandium, Selenium, Silicon, Silver, Strontium, Tantalum, Tellurium, Terbium, Thallium, Thulium, Tin, Titanium, Tungsten, Vanadium, Ytterbium, Yttrium, Zinc, Zirconium, oxidized forms thereof, and/or the like.

In many embodiments of the invention, the substrate is heated by a heater controlled to provide a temperature suitable to bake, dry, anneal, sinter, or melt materials deposited on the substrate. In some embodiments, gradients of material deposited in layers over each other can be heated to fuse the material components of each layer into a combinatorial material of substantially uniform composition through the thickness of the deposited material. Heaters can control the temperature of a substrate at desired temperatures from less than about 100° C. to about 2000° C. or more, from about 200° C. to about 1500° C., from about 450° C. to about 1000° C., or about 500° C. Substrates can be any material appropriate for the formation, analysis, or use of the material gradient deposited thereon. Representative substrate materials include, e.g., metals, glass, ceramics, semiconductors, polymers, carbon, silicon, and/or the like.

The material gradients of the invention can be analyzed or screened for useful characteristics. The gradient can be analyzed for properties, such as light absorbance, electromagnetic radiation, a size or shape, a voltage, a voltage in response to a pressure, a voltage in response to light exposure, electrical resistance, phosphorescence, fluorescence, and/or the like. The systems can include detectors to scan, screen or interrogate the gradients. The detectors can be, e.g., spectroscopes, magnetometers, microscopes, voltage meters, ohm meters, fluorometers, and/or the like. The detectors can detect characteristics, e.g., at one location on the deposition surface at time or can detect characteristics on the entire deposition surface at once.

In the methods and systems, many process parameters or components can be controlled manually or through automation. In preferred embodiments, a computer is interfaced with the system to control, e.g., a target bias voltage, an ion source current, rotation of a substrate, a thickness of a deposited layer, the orientation motion of the one or more shutter devices, the blocking motion of the one or more shutters, a gas flow, a chamber gas pressure, heating of the substrate, and/or the like.

The present invention includes combinatorial libraries produced using the systems of the invention and/or according to the method of the invention, as described herein.

### Definitions

Unless otherwise defined herein or below in the remainder of the specification, all technical and scientific terms used herein have meanings commonly understood by those of ordinary skill in the art to which the present invention belongs.

Before describing the present invention in detail, it is to be understood that this invention is not limited to particular devices or biological systems, which can, of course, vary. It is also to be understood that the terminology used herein is for the purpose of describing particular embodiments only, and is not intended to be limiting. As used in this specification and the appended claims, the singular forms “a”, “an” and “the” include plural referents unless the content clearly indicates otherwise. Thus, for example, reference to “a component” can include a combination of two or more components.

Although many methods and materials similar, modified, or equivalent to those described herein can be used in the practice of the present invention without undue experimentation, the preferred materials and methods are described herein. In describing and claiming the present invention, the following terminology will be used in accordance with the definitions set out below.

The term “combinatorial library”, as used herein, refers to a collection of two or more different compositions created by combination of two or more different materials in a chemical reaction, amalgamation, or crystallization.

The term “target”, as used herein, refers to one or more target materials that are intended to be sputtered from the target by ions from an ion source for deposition onto a substrate deposition surface.

The term “sputter”, as used herein, refers to ejection of material (atoms, ions, and/or molecules) from a target surface by the impact of an energetic particle. The particle is typically an ion.

The term “ion source”, as used herein, refers to a source of ions that can be directed to impact (illuminate) and sputter target materials from a target. Typical ion sources include filament-driven DC ion sources, radio frequency ion sources, RF magnetron sputter guns, and the like, that can produce and accelerate ions. In some embodiments of the invention, the direction and energy of ions striking a target from an ion source can be modified (influenced) by controlling a target voltage bias.

The term “illuminate”, as used herein, refers to direction of ions to impact target surface material with sufficient energy to release one or more target materials from the target. Illumination of a target can result solely from acceleration and direction of ions onto the target directly from the ion source and/or from target bias voltage attraction and acceleration of ions.

As used herein, the term “substrate” refers to a material having a rigid or semi-rigid deposition surface onto which sputtered target materials are intended to be deposited.

A “shutter device”, as used herein, refers to a shutter functionally associated with a drive mechanism that can move the shutter in a blocking motion. The shutter device can be capable of moving between orientation coordinates around an axis normal to a substrate deposition surface. Optionally, the orientation coordinates of the shutter device can be changed by motion of the deposition surface.

The term “orientation motion”, as used herein, refers to relative motion between a substrate deposition surface and a shutter device or mask that changes the orientation coordinate of the shutter device or mask. Orientation motion can bring a mask or shutter device to a desired orientation coordinate, thus establishing, e.g., the orientation of a mask shadow or shutter blocking motion during material deposition.

As used herein, “orientation coordinates” refer to locations for masks or shutter devices around an axis normal to the deposition surface that establish the orientation of a mask shadow or shutter blocking motion. Orientation coordinates are fixed relative to the deposition surface and can be expressed, e.g., as X and Y coordinates (or as radians and distance) in a plane parallel to the deposition surface, perpendicular to the normal axis, and centered on the normal axis.

A blocking motion, as used herein, refers to a motion of a shutter across a deposition surface that progressively blocks and/or unblocks the deposition surface from deposition of sputtered materials. The orientation coordinate of the shutter device at the time of the blocking motion establishes the orientation of the shutter blocking motion and ultimately, e.g., the orientation of a sputtered target material gradient across the deposition surface.

A “mask”, as used herein, refers to a perforated obstruction positioned between a target and a deposition surface that partially obstructs and partially permits sputtered material deposition through the mask onto the deposition surface. The mask can have patterned perforations to cast a patterned shadow of material on the surface, thereby controlling the distribution of deposited material on the surface. The orientation of a mask shadow on a deposition surface can be controlled by the orientation coordinate of the mask relative to the deposition surface.

### BRIEF DESCRIPTION OF THE DRAWINGS

FIGS. 1A to 1C are schematic diagrams showing deposition of gradients overlapping in three orientations to form a combinatorial library.

FIG. 2 is a schematic diagram showing an exemplary system of the invention including target bias voltage control, blocking motion of a shutter, and orientation motion of a shutter device.

FIG. 3 is a schematic diagram showing gradient deposition using single source illumination control with target bias voltages.

FIGS. 4A and 4B are schematic diagrams showing a substrate and shutter device mounted on a common rotation assembly.

FIG. 5 is a schematic diagram of an exemplary system having components monitored and/or controlled by a computer.

FIG. 6 is a schematic diagram of a gradient deposition system having two ion sources and two shutter devices.

FIG. 7 is a schematic diagram of a gradient deposition system with illumination by target bias and showing a shuttle mechanism for driving orientation motions around a track.

FIGS. 8A and 8B are schematic diagrams directed to a gradient deposition system having a mask between the target and substrate.

FIGS. 9A and 9B are schematic diagrams showing deposition of materials in linear gradients with opposite orientations.

### DETAILED DESCRIPTION

The present invention includes methods and systems for deposition of material gradients onto substrates. Systems of the invention can include controllable ion sources, targets, shutters, masks, and/or substrates. Methods of the invention can include, e.g., control of gradient deposition by controlling target voltage biases, shutter motions, and/or substrate rotation. The systems and methods can facilitate, e.g., formation of gradients at multiple orientations, and deposition of multiple materials with various proportions.

The systems can include ion sources directed to voltage biased targets for sputtering and deposition of target materials past a moving shutter onto a substrate to form gradients of materials. Gradients can be made more consistent and uniform by mounting the substrate on a rotation assembly. The profile of a gradient can be regulated by the presence of masks and/or the motion of shutters between the target and substrate. The orientation of gradients can be controlled by the orientation of the mask and/or shutter relative to the substrate.

In the methods, e.g., a shutter can be moved between orientation coordinates to establish gradients at different orientations. The bias voltages of targets can control what targets are illuminated by ions and the proportions of materials sputtered from the targets. Adept control of target biases, shutter orientation, mask orientation and/or substrate position, can allow deposition of any number of unique and desirable materials gradients.

Methods of Depositing Gradients

The methods of depositing gradients generally include controlling the relative positions of a substrate deposition surface and a shutter device. For example, gradients of materials can be deposited by illuminating a target with ions to sputter material from the target, moving a shutter across the deposition surface in a blocking motion that progressively blocks and/or unblocks deposition to the surface to form a gradient of the sputtered material on the surface, moving the shutter to a different starting position (orientation coordinate) so that the shutter blocking motion has a new orientation relative to the deposition surface, moving the shutter in the blocking motion while material is sputtered from another target to form a second gradient of a different material in a new orientation. The present methods allow control of process variables to prepare a broad range of desired material arrays on substrate deposition surfaces.

In one embodiment, a target bias voltage of two or more targets can control illumination of the targets and/or the relative proportions of materials sputtered from the targets. For example, an ion source can direct positively charged ions into a deposition chamber under a vacuum. Two of three targets can be biased to negative DC voltages to attract and accelerate the ions onto their surfaces (illumination) to sputter material from the two targets. The bias voltages can be controlled, e.g., so that the amount of material sputtered from one target is twice the amount sputtered from the second target. The proportionately sputtered material can be deposited onto a deposition surface of a substrate while a shutter moves at a constant speed back and forth across the deposition surface. At this stage, a gradient of the two materials in constant relative proportions can be produced in an orientation controlled by the direction of the shutter motion but with a greater amount of material deposited (thicker deposition) at the far end of the shutter blocking motion and a thinner deposition at the end near the shutter device and orientation coordinate. The shutter can be moved to a new orientation coordinate, e.g., 180 degrees from the original position relative to the substrate. The bias voltage of the two targets can be neutralized (or made positive) and a negative voltage can be applied to the third target, causing it to be illuminated with ions to sputter material from the third target. Shutter blocking motion from the new orientation coordinate can result in deposition of material from the third target in a gradient oriented with more material at the thin end of the first gradient and less material deposited at the thick end. As can be appreciated from the description above, two or more overlapping gradients of different materials can be created from depositions controlled by target biasing and/or shutter orientation.

In another embodiment, the substrate is rotated, e.g., to provide uniform exposure to material sputtered from different targets. The substrate can be mounted to a rotation assembly along with a shutter device. The shutter device, including a movable mount and a shutter capable of a blocking motion across the substrate, can stay at the same orientation coordinate relative to the substrate deposition surface while the substrate is rotated (i.e., they can rotate together on the same assembly). In some embodiments, the shutter device can move in an orientation motion around the rotation assembly to different orientation coordinates so that, although the substrate and shutter spin together, the shutter can be moved to new positions (orientation coordinates) relative to the substrate for deposition of gradients in new orientations.

Illuminating Targets

Targets can be illuminated by a bombardment of particles that causes target constituent materials to be released (i.e., sputtered) from the target surface. The particles are typically ions from an ion source that supplies the ions in a purity, trajectory, current, and/or energy suitable for the particular deposition method. Targets can be illuminated directly by mechanical alignment of an ion beam, indirectly by electrostatic or electromagnetic deflection of an ion beam, and/or by target bias voltage attraction of ions from ion source.

In many embodiments, targets are solid disks having a surface of target material exposed for sputtering and deposition onto a substrate in a deposition chamber environment. The target material can be any material or combination of materials that can be released by ion illumination for deposition. The target materials are typically metals, such as, e.g., Aluminum, Antimony, Barium, Bismuth, Boron, Cadmium, Calcium, Carbon, Cerium, Chromium, Cobalt, Copper, Dysprosium, Erbium, Europium, Gadolinium, Gallium, Germanium, Gold, Hafnium, Holmium, Indium, Iridium, Iron, Lanthanum, Lead, Lithium, Lutetium, Niobate, Magnesium, Manganese, Molybdenum, Neodymium, Nickel, Niobium, Palladium, Permalloy, Platinum, Polonium, Praseodymium, Rhenium, Rhodium, Ruthenium, Samarium, Scandium, Selenium, Silicon, Silver, Strontium, Tantalum, Tellurium, Terbium, Thallium, Thulium, Tin, Titanium, Tungsten, Vanadium, Ytterbium, Yttrium, Zinc, and Zirconium. The target materials can be in elemental form, present as compounds, and/or can include mixtures of elements or compounds.

Ion sources can be “ion guns” that accelerate ions into a deposition chamber containing one or more targets. A typical ion source includes a chamber to generate a plasma of ions, a cathode and anode to accelerate the ions, and electromagnetic lenses to focus and direct the ions in a beam. Ion sources can generate a plasma of ions, e.g., by heating an alkaline metal filament or by electron impact ionization from bombardment of a gas with high energy electrons. The ions can be accelerated, e.g., by electrostatic or electromagnetic fields, e.g., in a manner similar to the classic cathode ray tube, to create in a beam of ions. The beam can be redirected or rastered by passage through fields controlled by electrostatic plates or deflection coils. Ion source voltages and chamber gas pressures can be adjusted to affect the energy of the beam, possibly slowing the beam to generate a plasma of ions in the deposition chamber.

Targets can be controllably illuminated by ion beams using mechanical alignment or electromagnetic alignment. For example, the selection of a target for illumination can be by mechanical alignment (aiming) the ion source at the desired target, and/or by deflection of an ion beam by magnetic or electrostatic field lenses, to strike the target. To illuminate two or more targets at the same time, two or more ion sources can be separately directed at the targets. To control the proportions of materials sputtered from two or more targets, the ion energy and ion current amplitude from each ion source to each target can be controlled. To change targets, new targets can be moved into the paths of the beams, or the beams can be mechanically or electronically redirected to the new targets.

In certain embodiments of the invention, illumination of targets depends on target voltage bias. For example, an ion source can release a low energy beam or plasma into the deposition chamber without direct targeting onto the desired target. The target can be in electrical contact with a negative bias voltage that attracts the positive ions from the plasma or beam to strike the target. The amplitude of the bias voltage can affect the energy and/or quantity of ions that strike the target. In typical embodiments, the bias voltage in contact with targets intended to be illuminated ranges from about −10 V to about −2000 V, or more, from about −50 V to about −1000 V, or from about −100 V to about −500V. In the case of illumination with negatively charged ions, the typical bias voltage ranges would have about the same magnitude, but with a positive charge.

In some embodiments, a single ion source can selectively illuminate two or more targets at the same time under the control of voltage biasing. For example, a single ion source can emit positive ions into a deposition chamber as a low energy beam or plasma. A first target in the chamber can be connected to a strongly negative bias voltage, a second target to a moderately negative bias voltage, and a third target to a positive bias voltage. The first target can attract a large proportion of the ions and accelerate them to a relatively high energy level to impact the first target and sputter a relatively large quantity of material. The second target can attract a smaller proportion of the ions and accelerate them to a relatively lower energy level to impact the second target and sputter a relatively small quantity of material. Control of the relative voltages between the targets can control the proportions of materials sputtered from the two targets into the deposition chamber space. The positive voltage of the third target can substantially prevent the positive ions from striking that target and prevent material from being sputtered from the third target. New targets and sputtering proportions can be selected, e.g., by appropriately changing the bias voltages of targets in the chamber.

Depositing Materials onto Substrates

When targets and substrates are placed together in a deposition chamber, material sputtered from the target can diffuse and become deposited onto the substrate. The deposition can be affected, e.g., by the relative geometry of deposition system components, the choice of target materials, the intensity of the ion beam, the choice and pressure of gasses, the choice of substrate materials, and/or the like.

The deposition chamber typically provides an environment of gasses at a relative vacuum (less than atmospheric pressure), e.g., to minimize deposition impurities, avoid interference with the ion beams, facilitate migration of sputtered material, and reduce unwanted chemical reactions of the sputtered material with the atmosphere. The pressure inside a deposition chamber is typically less than 10 torr, 1 torr, 10⁻¹ torr, 10⁻² torr, 10⁻³ torr, 10⁻⁴ torr, 10⁻⁵ torr, 10⁻⁶ torr, or less. In a typical process, the chamber atmosphere is pumped down to less than 10⁻⁶ torr to remove oxygen and impurities. Vacuum pressures are typically somewhat higher while targets are being illuminated. The chamber can have, e.g., a cuboidal (e.g., 6-walled box structure) geometry with system components (such as, targets, substrates, and ion sources) mounted or intruding from separate walls. Other useful geometries include, e.g., spherical chambers, various polyhedrons, and chambers with various polygonal cross sections. The chambers are typically hermetically sealed with the internal gas pressure controlled by a vacuum pump, e.g., that is regulated by feedback from a pressure indicating device. The composition of the gas can be controlled by purging the atmosphere with the vacuum pump and introducing selected gasses through ports and/or ion sources.

In the sputtering process, the momentum of ions striking the target is transferred to target materials so that they are ejected from the target surface. The angle of ejection away from the surface may initially be approximately the incident angle of the ion onto the surface, but collisions of the ejected (sputtered) material with chamber gasses typically moderates transport of the sputtered material to a random walk (diffusion) through the gas.

Targets can be located in the chamber at positions where ion beams can be directed to illuminate their surface. Substrates are often located at positions near the targets to increase the efficiency of sputtered material deposition onto the substrate. However, because sputtered materials can move essentially by diffusion from the target to the substrate, portions of a substrate that are closer to the target can have more material deposited that portions of the substrate further from the target. Such uneven deposition can be reduced, e.g., by mounting targets and substrates with surfaces parallel to each other, and/or by rotating the substrate during deposition.

Forming Gradients

Gradients of materials can be deposited, according to the invention, by using shutters to progressively block and/or unblock the substrate deposition in timed sequence during deposition of sputtered material. In one embodiment, a shutter moves across the substrate in a blocking motion while substrate and shutter rotate together during deposition, resulting in uniform material deposited in a thickness gradient oriented according to the blocking motion. In another embodiment, a shutter can make a blocking motion for a material gradient in one orientation on the substrate, then the shutter can move to a new position (orientation coordinate) to make a blocking motion to form another material gradient in another orientation on the substrate. Optionally, target bias voltages can be controlled during deposition of the gradients to control what targets are sputtered, the rate of sputtering, and/or the proportions of materials sputtered from two or more targets.

Blocking motions move shutters across the deposition surface of a substrate, between the substrate and the target so that deposition of material onto portions of the substrate surface is progressively blocked and/or progressively unblocked by the shutter. The stroke range of the blocking motion can control the range of a gradient formed as a result of the blocking motion. The direction of the blocking motion can control the orientation of the gradient formed as a result of the blocking motion. Blocking motions can progress across the deposition surface in a variety of motions that can affect the gradient profile. For example, if the shutter moves in a halting stepped motion, a stepped gradient of deposited material thicknesses can be formed on the substrate. If the shutter moves in a constant linear motion, a linear gradient of material with a constantly changing thickness can be formed. Other shutter blocking motions that can be reflected in the gradient profile include, e.g., a geometric change in shutter velocity relative to the substrate deposition surface, a logarithmic change in velocity, a sigmoidal change in velocity, an orbital motion, and the like.

Shutter blocking motions move the shutter between the substrate deposition surface and the target. The shutter typically moves close enough to the surface so that diffusion of sputtered material between the shutter and deposition surface is not significant. The shutter can move, e.g., in parallel with the deposition surface at a distance from about 0 to about 5 cm, or from about 1 mm to about 1 cm from the surface.

The orientation of the blocking motion, and thus the orientation of the gradient formed on the deposition surface, can depend on the orientation coordinate the shutter is working from. Orientation coordinates are locations for shutter devices around an axis normal to the deposition surface that establish the orientation of a shutter blocking motion. As a practical matter, orientation coordinates are positions of a shutter, shutter mount, or mechanism (shutter device) that can dictate the relative motion of the shutter and substrate deposition surface during blocking motions and thus affect the distribution of materials being deposited on the substrate during a deposition process. The orientation coordinates of a shutter relative to a substrate can establish the starting point and ending point for blocking motions the shutter will make during a deposition.

Orientation motion can bring a shutter device to a desired orientation coordinate, thus establishing the orientation of a shutter blocking motion and gradient formation. To form two or more gradients with different orientations, a shutter can move in a blocking motion during deposition of a first gradient, then the shutter can be moved to a different orientation coordinate relative to the substrate (an orientation motion) before deposition of a second gradient with the shutter moving in a blocking motion from the new coordinate.

The orientation motion is typically a motion some degrees around an axis normal to the deposition surface. The axis is typically through about the center of the deposition surface. The orientation motion typically results in the shutter device being about the same distance from the substrate at the second coordinate as for the first coordinate. The shutter device typically rotates through the same angle as the angle of orientation change about the normal axis so that the shutter blocking motion remains directed across the deposition surface (i.e., the shutter continues to functionally “face” the substrate as it orbits the substrate during orientation coordinate changes). In some embodiments, the orientation motion can be accomplished by moving the substrate but not the shutter device. For example, the shutter device can be retained at an original position (e.g., relative to the outside world), while the substrate rotates to a new position that effectively brings the shutter device to a new orientation coordinate relative to the substrate, and can be considered an orientation motion. In another embodiment, the substrate does not move (e.g., relative to the chamber), but the shutter device moves around the substrate to a new orientation coordinate (e.g., an orientation motion around an axis normal to the deposition surface). In one embodiment, the substrate spins in a motion intended to obtain uniform deposition of materials, while the shutter device orbits the substrate about the same axis at the same rotation rate to maintain the same orientation coordinate during blocking motions and deposition of a first gradient. Before deposition of a second gradient, a new orientation is established by moving the deposition surface relative to the shutter device in an orientation motion, as described above. The orientation motion, of the shutter device and/or deposition surface, can take place while the substrate continues to spin, e.g., for deposition uniformity or after the substrate has stopped spinning.

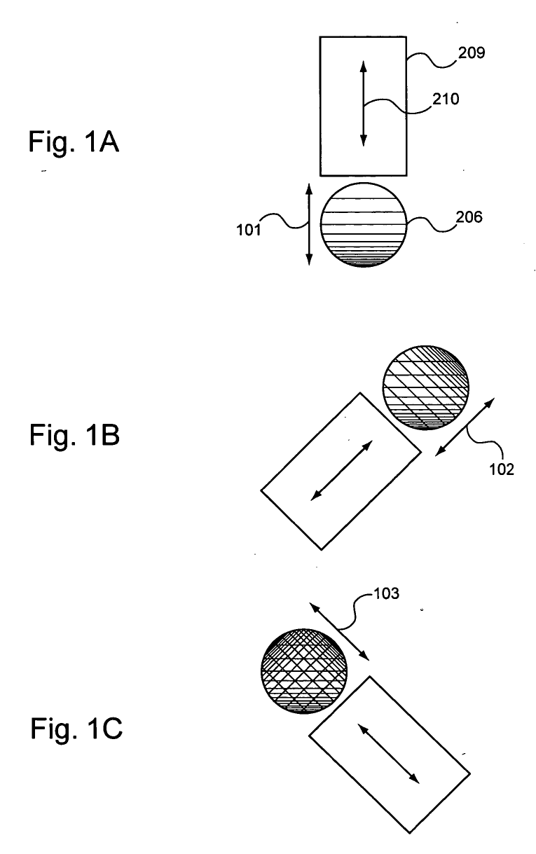

In a typical method of forming a combinatorial library, multiple gradients can be formed from two or more orientations. For example, as shown in FIGS. 1A-C, a first gradient 101 of material can be deposited onto a substrate 206 deposition surface in a first orientation (FIG. 1A). An orientation movement of the shutter to a new position (orientation coordinate) relative to the substrate establishes a second orientation of movement for blocking motion 210 of shutter 209 (see FIG. 1B). Blocking motion from the second orientation coordinate during a deposition process produces second gradient 102 shifted 120° from the orientation of the first gradient. Another orientation movement of the shutter to a third orientation coordinate establishes a third orientation of movement for the shutter blocking motion (see FIG. 1C). Blocking motion from the third orientation coordinate during a deposition process produces third gradient 103 oriented 120° from the previously deposited gradients. The gradients can overlap to provide, e.g., continuously changing proportions of the three deposited materials in a laminated film across the substrate surface.

Masks can be positioned between targets and substrates to form patterns or gradients of material on deposition surfaces. Optionally, the masks can be employed in combination with shutters. The masks can rotate along with rotating substrates while retaining orientation coordinates relative to the deposition surface, as described above for shutter devices. The masks can have patterned perforations to cast shadows during material deposition that provide desired gradient profiles.

In one embodiment, a patterned mask is placed close to, or in contact with, a deposition surface to create a “negative” image of the mask pattern in material deposited on the surface, as is known in the art.

In another embodiment, a mask is positioned between the target and deposition surface far enough from the surface to allow diffusion of sputtered material to create a poorly resolved, unfocused shadow. For example, a mask with perforations patterned to have slits with geometrically increasing widths can cast a diffuse shadow of sputtered material that is deposited in a gradient having a smooth geometrically changing thickness profile. Masks useful for casting diffuse shadows in the formation of smoothly deposited gradients can include, e.g., slits, dots, polygons, and other perforation shapes. The density of the perforations (holes) and/or diameter of the perforations can change from one end of the mask to the other in a manner describing desired gradient profiles. For example, a mask with uniform diameter holes that increase in number logarithmically from one end of the mask to the other can cast a shadow providing a gradient with a logarithmic thickness profile. Trigonometric effects of masks positioned at angles to the deposition surface can be considered, by one skilled in the art. Effects of various masks on gradient formation can be calculated or determined empirically.

As with shutter devices, masks can be moved between multiple orientation coordinates to form multiple gradients with different orientations on substrates. A gradient can be deposited through a mask in a first orientation, then the mask can be moved in an orientation motion relative to the surface before deposition of a second gradient. In an embodiment, the substrate, spinning for deposition uniformity, can be orbited by a mask so that the relative positions of the mask and deposition surface do not change while sputtered material is deposited through the mask. An orientation motion between the substrate and the mask can bring the mask to a new orientation coordinate for deposition of a new gradient in a new orientation.

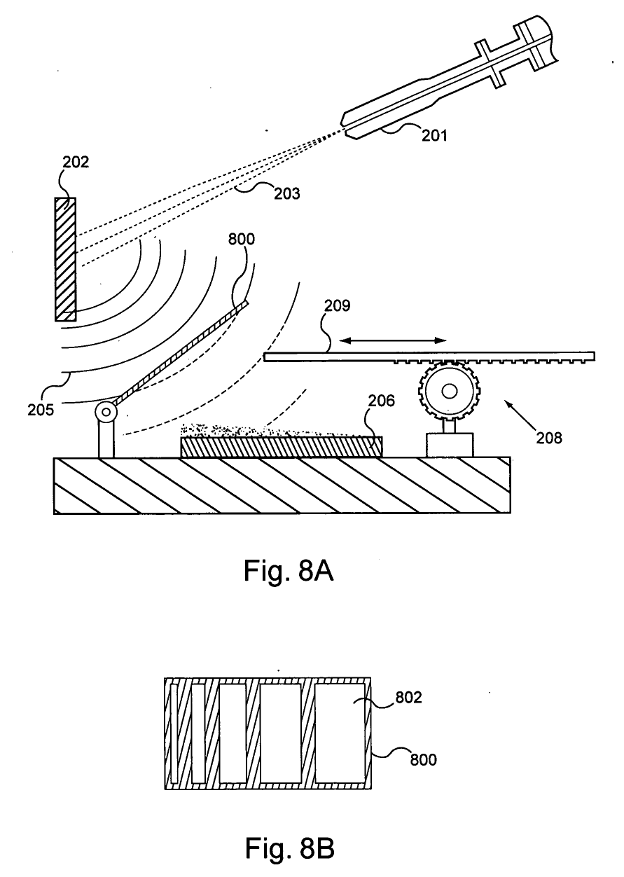

In certain embodiments, formation of gradients can employ both shutters and masks. For example, a mask can cast a shadow on a deposition surface while a shutter moves in a blocking motion to provide a desired gradient profile. A gradient can be formed on a substrate in one orientation established by a mask and another gradient can be established by a blocking motion of a shutter in the same orientation or in a different orientation than the mask gradient. Depending on the geometry of the deposition system, masks can be used to provide even deposition. For example, when a target and substrate are arranged at right angles from each other, the portion of substrate closest to the target can have more material deposited than portions of the substrate further from the target. A mask with a gradient of perforations can cast a shadow that results in deposition of material with an even thickness; addition of a moving shutter can then control orientation of a gradient. See, e.g., FIG. 8.

Multiple gradients can be formed on the same substrate. Gradients of different materials can be deposited with the same orientation or with different orientations. Two gradients, 3, 4, 5, 6, 8, 10, 50, 100 gradients, or more, can be deposited on a single substrate using the methods of the invention. Such gradients can be evenly spaced around a substrate, e.g., every 180°, every 120°, every 90°, every 72°, every 60°, and so on; or they can be unevenly spaced. Multiple gradients with the same or different profiles (linear, stepped, geometric, etc.) can be deposited on the same substrate.

Gradients can overlap each other to create combinatorial libraries without the need to melt tire gradient materials. The gradient films deposited can be so thin that the atoms or molecules of material deposited self align into uniform crystal structures. For example, overlapping gradients can be created, e.g., by depositing a first gradient at a maximum thickness in the range from about 10 Å to about 1000 Å, depending on the material. A second gradient can be deposited over the first gradient at a thickness about in the same range. The process can be repeated (e.g., using the rapidly reoriented shutters and/or masks of the present invention) many-fold to build up, e.g., a combinatorial gradient film uniform unlamented composition through the thickness from any point at the surface.

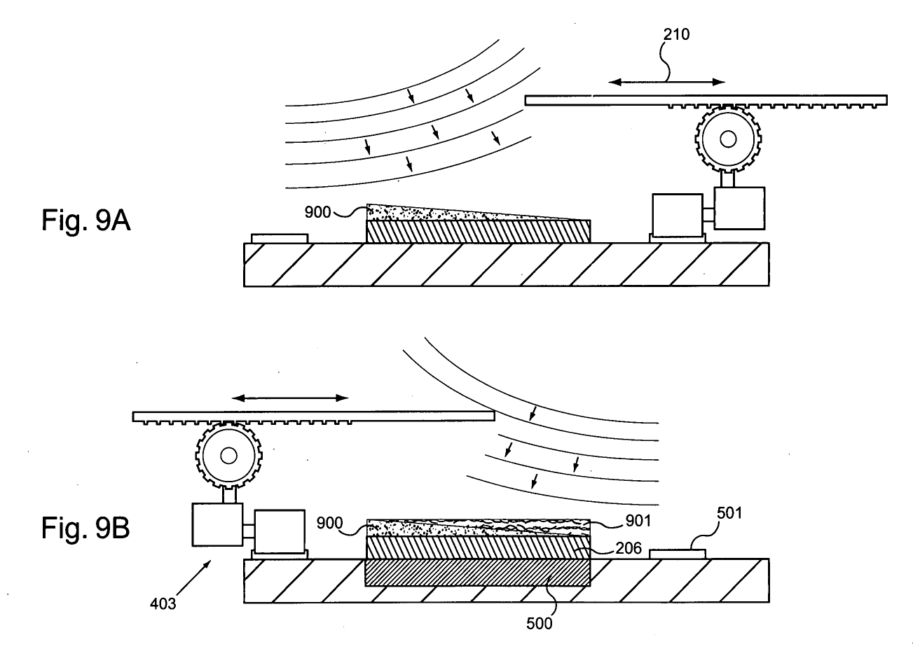

Gradients can overlap to form laminated structures. Layers of gradients can be deposited over each other to form layered structures with gradients in any desired orientations. For example, as shown in FIG. 9A, a first gradient 900 of a first material can be deposited in a first orientation. A second gradient 901 of a second material can be deposited in a second orientation 180° from the first, as shown in FIG. 9B. The second gradient will tend to level the deposition surface with the thick end of the second gradient covering the thin end of the first gradient, and the thin end of the second gradient covering the thick end of the first gradient. Such gradients can be useful, e.g., in screening for optimal layering in optics devices. Optionally, the overlapping gradient layers can be fused into a combinatorial gradient film with uniform composition through the thickness by application of heat to uniformly fuse the constituents through the depth of the gradients.

Gradients with changing materials proportions across the surface can optionally be generated by coordination of shutter blocking motions and the proportioning of material sputtered from two or more targets. For example, two targets with independently controllable illumination can be sputtered with proportions progressively changing from 100 percent first target sputtering and zero percent second target sputtering, to zero percent first target sputtering and 100 percent second target sputtering over a time period. Over the same time period, a shutter can progressively block deposition onto a substrate deposition surface in a single blocking motion across the surface. The result can be, e.g., a surface composition that changes from 100 percent material sputtered from the first target on the surface initially blocked by the shutter, mixed compositions of material from both targets in the middle of the surface, and 100 percent material sputtered from the second target near the surface finally blocked by the shutter. This method of making surface gradients with changing materials composition can include controllably changing sputtering proportions from any number of targets and/or changing of targets from one to another during the deposition process. The independently controllable illumination can be accomplished by using two or more ion sources with independently controllable beam currents and/or intensities. In a preferred embodiment, multiple targets are illuminated by a single ion source with independently controllable illumination provided by controlling bias voltage for each target.

Heating Substrates

In many cases, it is useful to control the temperature of the substrate during or after deposition processes. The substrate can be cooled or heated to maintain a desired deposition temperature. The substrate can be heated, e.g., to dry, bake, anneal, sinter, or melt the deposited material.

The substrate can be heated to remove gases, volatile materials, and contaminants. This procedure can beneficially take place in an atmosphere having a relative vacuum. This substrate bake out can occur at temperatures ranging from about 100° C. to about 500° C.

After deposition of materials onto substrates, they can be processed with heat, e.g., to provide more uniform compositions. Heating can allow crystal lattices to anneal to more homogenous or stable configurations. Mixed compositions, overlapping gradients, and/or laminated films can be fused by melting or sintering to provide uniform compositions through the thickness of deposited films. Depending on the materials involved, sintering or melting can require temperatures ranging from about 200° C. to about 1500° C., from about 400° C. to about 1000° C., or from about 500° C. to about 800° C.

Screening Gradients and Combinatorial Libraries

The gradient and combinatorial materials products made by the present methods can be screened for a variety of useful characteristics. A single gradient of one or more materials can provide a continuously variable selection of material quantities and/or proportions in one orientation. Multiple overlapping gradients of materials on a substrate can provide a variety of materials that vary continuously in two dimensions. Such gradients can represent a combinatorial library with, e.g., from hundreds to billions of different compositions from which to select an optimum composition for a particular use.

Gradients and combinatorial libraries of materials produced by methods of the invention can be screened to find, e.g., useful optical filters, reflectors, phosphors, fluorophores, superconductors, semiconductors, piezoelectric materials, photovoltaic materials, magnetic materials, crystal nuclei, catalysts, and the like. The gradients and libraries can be screened for useful characteristics by appropriate means, such as, e.g., spectroscopy, electromagnetic detection, microscopy, detecting a voltage, detecting a voltage in response to a pressure, detecting a voltage in response to light exposure, detecting electrical resistance or fluoroscopy. Screening methods can be discrete, sequential, or massively parallel. For example, characteristics of materials at library locations can be tested manually, one at a time. An automated system can systematically analyze locations in a library, e.g., in an X-Y plotted sequence. In many cases, library locations can be screened in parallel, e.g., by viewing with an array style detector, such as a charge coupled device (CCD). For example, a library can be screened for a desired fluorescence characteristic by illuminating the library with a selected excitation light wavelength and observing the entire library through a filter that passes a desired emission light frequency. Such observation can be, e.g., by the human eye or with the charge coupled device (CCD) of a digital camera.

To test effects of process variables on materials, replicate libraries of deposited materials can be prepared and the results of different treatments can be compared. For example, identical replicate combinatorial libraries of prospective phosphorescent materials can be prepared according to methods of the invention. A first library can be processed, e.g., by heating to 500° C., and a second identical library can be processed by heating to 600° C. The two libraries can be compared to determine an optimum combination of materials and temperature to provide a desired phosphorescence characteristic.

Systems for Deposition of Gradients

The present materials deposition systems can include, e.g., deposition chambers with functionally mounted ion sources, targets, substrates, shutters, masks, and/or voltage bias electrodes. The shutters can interact with other system components to prepare materials gradients and combinatorial libraries in a variety of ways. For example, materials gradients in two or more orientations can be formed by illuminating targets with ions to sputter material while a shutter moves across a deposition surface to form a first gradient, then illuminating different targets, moving the shutter to a new position (orientation coordinate) and moving the shutter across the deposition surface from the new position to form a second gradient with a different orientation.

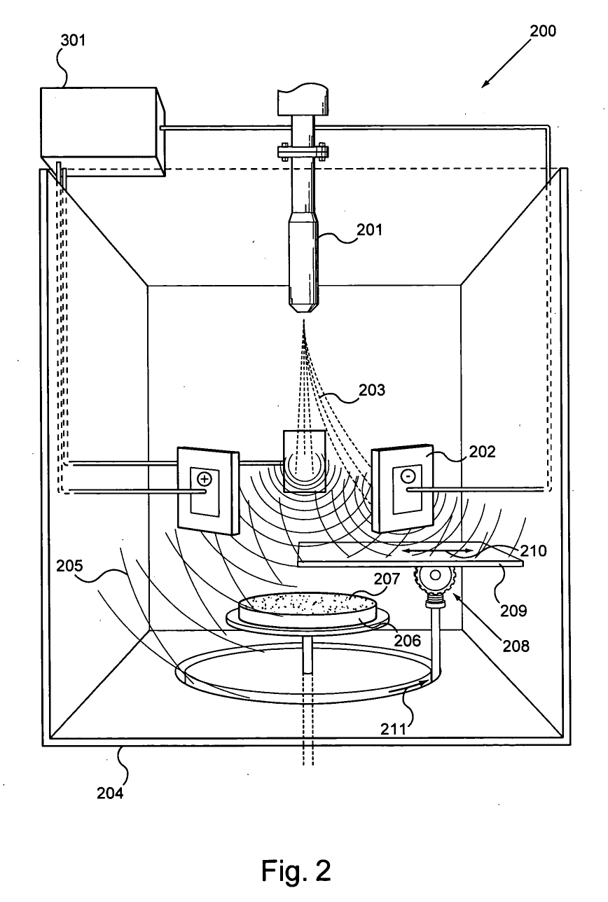

The deposition systems can include a shutter that can shift to different positions around a substrate to change the orientation of shutter blocking motion relative to the substrate, as shown, e.g., in FIG. 2. The system 200 for depositing gradients of materials can have, e.g., ion source 201 directed to illuminate a targets 202 with ions 203 in a deposition chamber 204 to sputter materials 205 from targets. Substrate 206 can be located in the chamber to receive sputtered material for deposition onto deposition surface 207. Shutter device 208 can be movably mounted in the chamber and have shutter 209 movably mounted so it can move back and forth across the deposition surface of the substrate. The shutter motion (blocking motion 210) during a deposition process can result in, e.g., a gradient with more material on the portion of the deposition surface that is blocked last (or least), and less material on the portion of the deposition surface that is blocked first (or most) by the shutter motion. After a first gradient is established, the entire shutter device can move (in an orientation motion 211) around, e.g., to another side of the substrate so that the shutter motion has a new orientation across the substrate. The ion source can be directed to illuminate another target to sputter a different material while the shutter moves in a blocking motion from the new orientation to form another gradient of material on the deposition surface in a different orientation from the first.

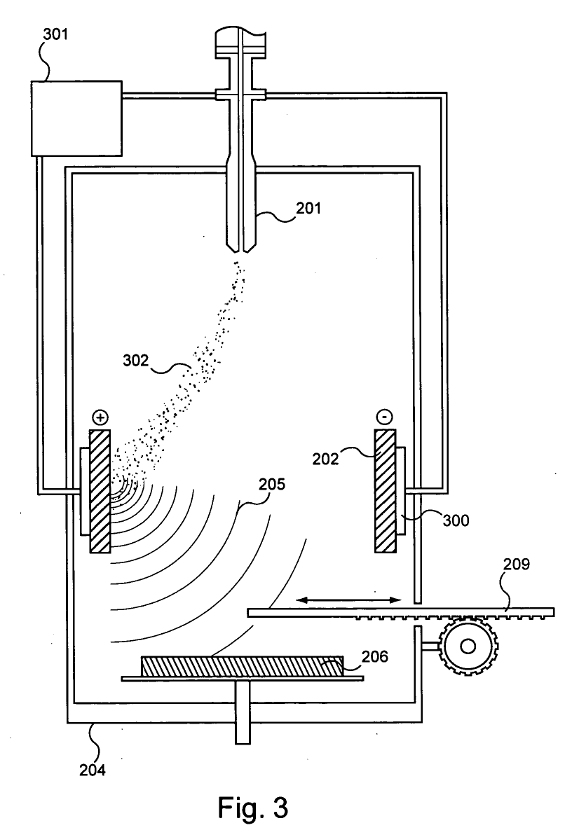

In another embodiment, the system, e.g., as described above and shown in FIG. 3, targets 202 are in electrical contact 300 with independently controllable target bias voltages from voltage controller 301. Single ion source 201 emits positively charged ions to produce a plasma 302 in chamber 204. The chamber can include several targets. A target with a strong negative bias voltage will attract and accelerate ions from the plasma to sputter material 205 from the target surface. A target with a positive voltage bias will not experience significant sputtering impacts from the ions. Controlled bias voltages in electrical contact with targets can quickly and separately control sputtering from multiple targets, e.g., while orientation motions and blocking motions of a shutter device establish orientation of gradients being deposited onto the substrate.

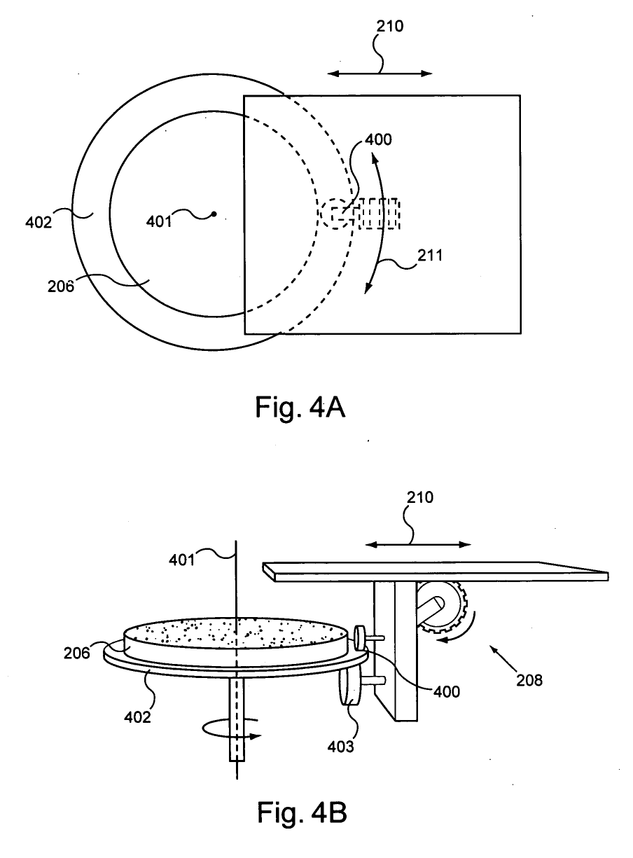

In yet other aspects of the systems, e.g., as described above and shown in FIG. 4, the shutter device 208 can be mounted so that it retains a relative position (orientation coordinate 400) around an axis 401 normal to substrate deposition surface, even when the substrate is rotated. This can be accomplished, e.g., by mounting both substrate 206 and the shutter device on a common rotation assembly 402. The shutter device can optionally be movably mounted to the rotation assembly (e.g., with shuttle mechanism 403) so that, e.g., the shutter device can be moved to a new orientation coordinate relative to the deposition surface between gradient depositions.

Deposition Chambers

Deposition chambers can provide mounting surfaces for system components and are typically hermetically sealable to allow control of the internal gas environment. The deposition chambers are typically made of stainless steel and can have ports and windows for internal access and viewing.

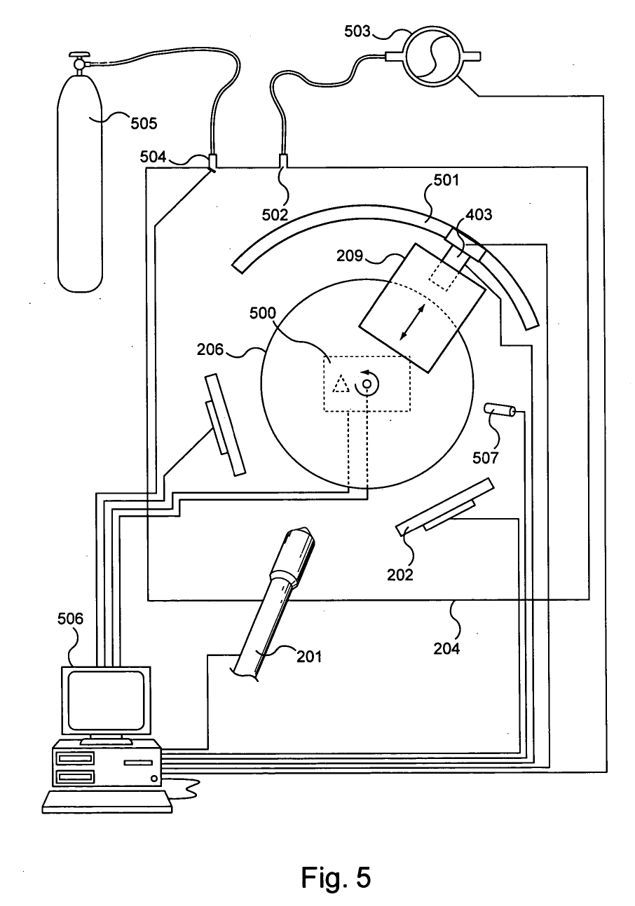

In one example of a system arrangement, the chamber can house ion source 201, targets 202, substrate 206 in contact with heater 500, and shuttle mechanism 403 on track 501 with shutter 209, as shown in FIG. 5. The chamber can include vacuum port 502 in fluid contact with vacuum pump 503 so that the internal atmosphere can be evacuated. Gas control valve 504 can be in fluid contact with gas source 505 allowing the gas composition of the internal atmosphere to be controlled. An optical device 507 can be directed to monitor the thickness of material deposition.

In many cases, the vacuum pump evacuates air from the deposition chamber and the internal environment is purged with an inert gas, such as argon, under continued vacuum conditions before beginning a deposition process. Certain ion sources introduce gasses during operation and these gasses can be removed by operation of the vacuum pump to maintain a constant selected pressure in the chamber.

Targets

Targets are the source of sputtered materials deposited onto substrates in deposition systems of the invention. The surface of a target can have any of a variety of materials intended for sputtering by ion impact from an ion source. Targets are mounted in the deposition chamber at a location open to illumination by the ion source and often in close proximity to the substrate deposition surface. Targets can be in electrical contact with voltage controllers to control sputtering rates of materials from the target.

Targets can be structures made entirely of the target material. Optionally, targets can be structures made of solid materials (such as metals, ceramic or glass) to facilitate mounting and handling, but with a layer of target material on a surface for illumination by the ion source.

As discussed in the Methods section above, the target materials can include, e.g., Ag, Al, Au, Ba, Bi, Ca, Ce, Cd, Co, Cr, Cu, Eu, Er, Fe, Ga, Gd, Ge, Hf, In, Ir, La, Lu, Mg, Mn, Mo, Nb, Nd, Ni, Pb, Pd, Po, Pr, Pt, Ru, Sb, Sc, Si, Sm, Sn, Sr, Ta, Te, Ti, V, W, Y, Yb, Zn, Zr, mixtures thereof, and oxidized forms thereof. Targets can include other materials known in the art that can be usefully sputtered for deposition onto a substrate. Materials sputtered from targets can react with reactive gasses in the chamber, in some embodiments, to form modified sputtered materials for deposition.

When multiple targets are present in the same deposition chamber, cross contamination can take place when material from one target is deposited onto another target. One way to minimize this problem is to place shields or baffles that physically separate the targets, e.g., so that they are not in line of sight to each other.

When targets are illuminated with ions, a charge can be imparted to the target. Build up of the charge can repel additional ions from impacting the target. This problem can be avoided by, e.g., grounding the targets, applying neutralizing voltages to the targets, or by illuminating the targets with neutralizing ions or electrons.

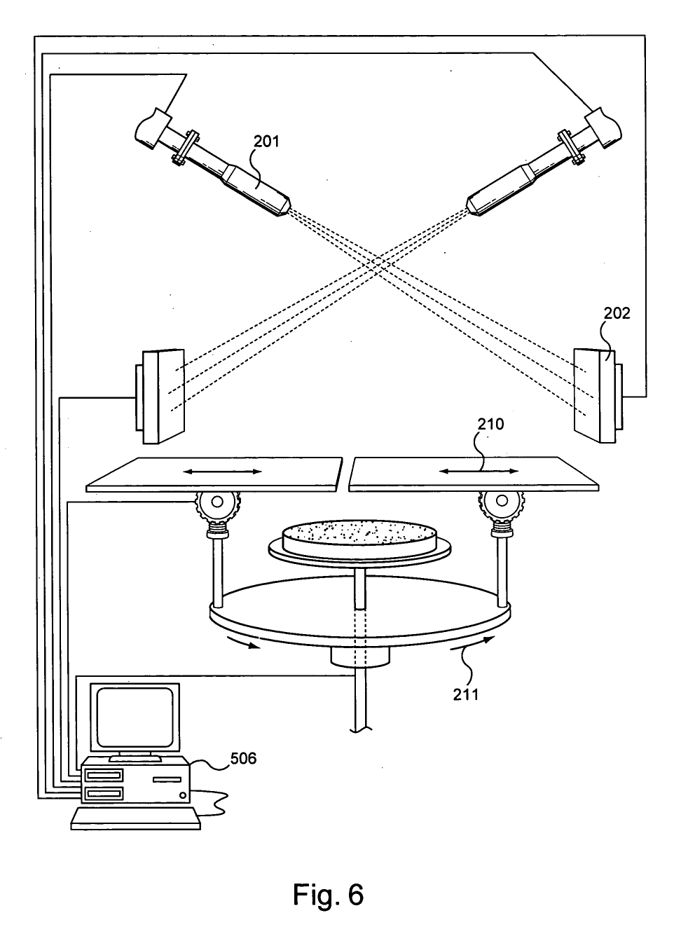

Targets can be selectively illuminated, e.g., by placing them in the path of an ion beam. Where a deposition process requires sputtering from two or more targets at different times, the targets can be selected by moving the targets sequentially into the ion beam path, or by realigning the ion beam (mechanically or electronically) to illuminate targets located at different positions in the chamber. Optionally, as shown in FIG. 6, each target can be paired with an ion source so that target selection can be by activation of ion sources.

Targets can be selected for illumination, e.g., by controlling target bias voltages, as discussed above in the Illuminating Targets section. With target bias voltage control, the ion source typically injects ions into the chamber as a plasma or low energy beam (e.g., with insufficient energy to sputter material from the target). Targets are selected for illumination by applying a voltage having the opposite sign of the ions so they are attracted to impact the target. Targets that are not selected can have a neutral voltage or a same sign voltage that repels the ions from the target. Bias voltages can be supplied to the targets through electrical contact with voltages from a voltage controller. In certain embodiments, targets can be individually selected, or selected in various proportions by appropriate application of bias voltages to two or more targets in the deposition system.

Ion Sources

A variety of ion sources are functional in the deposition systems discussed herein. Depending on the particular system configuration, the ion source can be selected to provide ions of any charge, velocity, energy, and/or current. The ion source can emit, e.g., a plasma, low energy beam, or high energy beam into the chamber. The ion beam can be aligned to directly illuminate and impact targets of choice. Optionally, illumination can be controlled by target bias voltage, as described above.

Typical ion sources include filament-driven DC ion sources, radio frequency ion sources, RF magnetron sputter guns, and the like, that can produce and accelerate ions. Exemplary ion sources useful for implementing the present invention include end-Hall or closed drift Hall Ion sources such as the MARK II™ source of Commonwealth Scientific Corp. In one embodiment, each ion source is a divergent ion current source that generates a divergent ion beam characterized by an ion current distribution that varies in accordance with the equation: ion current=Jₒ cos θ; where θ is an angle between the central axis of the divergent ion beam and a direction of the ion current, and Jₒ is the ion current density along the central axis. Another useful ion source is the IonEtch ion gun with a filamentless ion source based on a microwave plasma discharge. The Ionetch works by coupling microwave energy into a coaxial waveguide and from there via evanescent wave coupling, into a plasma chamber. The intense oscillating electric fields cause the gas to break down and a plasma discharge to take place. An axial magnetic field around the chamber further enhances the plasma density via the Electron Cyclotron Resonance (ECR) effect. Ions can be extracted from the plasma using simple two or three grid single-hole extraction optics for direction into the deposition chamber.

In a typical ion source, a gas (for example, Ar, Xe, N₂, or O₂) can be supplied by a gas controller (or mass flow controller) to be ionized by the ion source. The volume of gas output by the gas controller can be varied by a computerized process controller. An ion source power supply can be coupled to the ion source to supply a control voltage to the ion source. The output of the ion source power supply can be varied by the process controller. Control signals can be supplied to both the ion source power supply and an ion source gas controller, in order to vary the magnitude of the ion current into the chamber or at the target. The ion current can vary linearly with changes in the flow rate of the gas supplied to the ion source. In addition, for a given flow rate of gas supplied to the ion source, the ion current generated from the ion source and flowing into the chamber can vary proportionately with the magnitude of the voltage control signal supplied by ion source power supply to the ion source. Thus, depending on particular process requirements, the ion current and/or energy can be controlled.

Ion sources can have lens or beam displacement elements, e.g., to focus, diffuse or redirect the beam. The beam can be diffused to distribute the ions broadly over the target. The beam can be rastered in a sweeping or random motion to provide more uniform erosion of the target.

Substrates

Substrates provide a deposition surface to receive sputtered materials in production of materials gradients and combinatorial materials libraries. Substrates are typically rigid or semi rigid structures that can passively receive deposited film or that can play a role in the film function or analysis of a deposited film. The substrates are generally structurally sound, stable to process conditions, and compatible with the intended use of the deposited material.

Substrates are typically solid materials and often take the form of a disk. Substrates are often made of materials, such as metals, glass, ceramic, semiconductors, polymers, carbon, silicon, and/or the like.

Substrates can be mounted in the chamber so that sputtered material is efficiently deposited onto the deposition surface. In many embodiments, the substrate is in close proximity to the targets. The substrate can be mounted to a rotatable base (e.g., a rotation assembly) allowing more uniform deposition while the substrate rotates in a non-uniform environment of sputtered material. For example, in cases where one part of the substrate is closer to the target than another, rotation can avoid thicker build up of material at the end of the substrate nearest to the target. In cases where material is deposited from two targets at the same time, rotation can help provide deposition of the mixed composition with uniform proportions in a film having a uniform thickness across the substrate. In many cases, more uniform and consistent gradients can be formed using shutters in combination with substrate rotation.

Shutter Devices

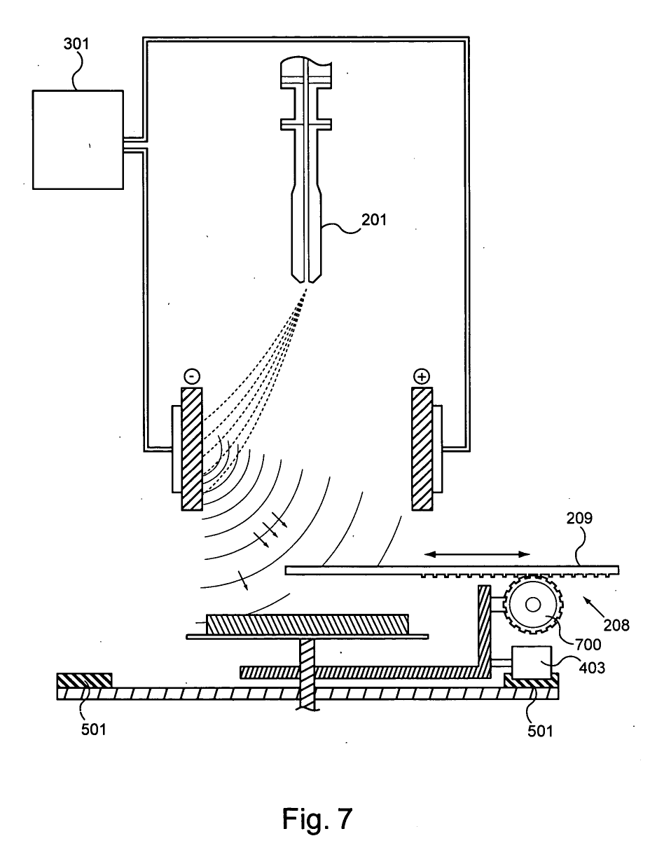

Shutter devices 208 include at least a shutter 209 and drive mechanism 700 for moving the shutter in a blocking motion, see FIG. 7. Shutter devices can include shuttle mechanism 403 to move the shutter device around the substrate in an orientation motion.

Shutters function to block all or part of a substrate deposition surface from deposition of sputtered material. The shutters can be of any shape and size, but are typically, e.g., a sheet of rigid or semi-rigid material with a straight edge that moves across the deposition surface between the substrate and target. Shutters are generally impermeable to sputtered materials.

The shutter can be mounted to the shutter device so that it can move between a substrate and target during a blocking motion. The shutter is typically mounted so that there is little or no clearance between the shutter and substrate during blocking motions. Optionally, the shutter is mounted so that it is spaced from the substrate, e.g., ½, ¼, 1/10, 1/100, or less of the distance from the substrate deposition surface to the target during the blocking motion.

A drive mechanism of the shutter device moves the shutter in a blocking motion across the deposition surface. The drive mechanism can be, e.g., a stepper motor turning a gear meshed with a rack of cogs on the shuttle so that turning the motor causes the shutter to slide in a blocking motion. The stepper motor can receive power from a controller that controls, e.g., the speed and type of shuttle blocking motion. For example, the motor (and therefore the shuttle) can be controlled to move slow or fast. The motor can drive the shutter intermittently, continuously or with changing speed to provide shutter blocking motions that are, e.g., stepped, linear, or changing according to a desired mathematic formula. Shutter blocking motions can be repeated during deposition of a material, so that build up of deposited material with the desired gradient profile can accumulate with each blocking motion.

Shutter devices can move in an orientation motion provided, e.g., by a shuttle mechanism. The shuttle mechanism can be, e.g., a stepper motor with a gear engaging cogs in a track around a substrate. The shuttle mechanism can be, e.g., a turntable on which the shutter and drive mechanism are mounted; the turntable can be driven directly or indirectly by a motor in communication with a controller. Such a turntable can rotate, e.g., in a plane parallel to the plane of the deposition surface to move the shutter and drive mechanism in an orbital motion around the substrate to any desired orientation coordinate. In many embodiments, the orientation motion includes, e.g., an orbital motion of the shutter device around the periphery of the substrate and an equivalent rotation of the shutter device so that the device continues to face the substrate. For example, as the shutter device proceeds in a 180° orbital motion around the substrate, it also rotates 180° so that the same side of the shutter device continues to face the substrate. In this way blocking motions continue to be directed across the substrate no matter the orientation coordinate.

In one embodiment of the shuttle mechanism, it can be mounted to a rotation assembly allowing the shutter device to rotate (e.g., orbit) along with a rotating substrate, e.g., during a deposition process, but also allowing the shutter device to move to another orientation coordinate between deposition processes, as shown in FIG. 5.

In certain aspects of the invention, a mask can be mounted to a shuttle mechanism to be moved in an orientation motion to a new orientation coordinate.

Masks

Masks are typically rigid to semi-rigid sheets perforated with a pattern that functions to screen a portion of sputtered material from deposition on a substrate. Masks can be employed between substrates and targets to provide patterned depositions or modified gradient profiles, as discussed in the Forming Gradients section or as shown in FIG. 8.

As shown in FIG. 8A, mask 800 (side view) can be mounted between target 202 and substrate 206. The mask can be mounted between shutter 209 and the target, or optionally, between the shutter and the substrate. Masks can have perforations that allow sputtered materials to pass (see FIG. 8B, mask top view) while a portion of the sputtered material is blocked by the physical mask.

Masks can block a portion of sputtered material from deposition on a substrate and can allow a portion of sputtered material to be deposited on the substrate. Sharp patterns corresponding to perforations in the mask can be deposited onto the substrate, e.g., if the mask is mounted close to the substrate and/or if the sputtered material travels in a straight line from a fixed point. More diffuse patterns, such as, e.g., gradients without sharp steps, can be formed if the mask is mounted a substantial distance from the substrate deposition surface and/or if the sputtered material moves in a non-linear or random (diffused) path, and/or if the material is sputtered from a planar source. Movement of the mask can reduce the sharpness of deposited patterns.

Gradients

The present systems can form gradients of deposited material on substrate deposition surfaces. The gradients can include, e.g., one or more materials, deposited in one or more orientations, with one or more gradient profiles.

A gradient of a single material can be formed by illumination of a target having a single material and deposition onto a substrate through a mask and/or moving shutter. The resultant gradient can be, e.g., a film of the material that changes thickness at points across the deposition surface.

A gradient of multiple materials can be formed in a variety of ways. For example, a target having multiple material components can be illuminated to sputter multiple materials onto the substrate through a mask and/or past a moving shutter. Optionally, multiple targets of different materials can be illuminated at once to sputter multiple materials onto the substrate simultaneously through the mask and/or shutter. The resulting gradients can be that are thicker, e.g., toward one side of the substrate, with unchanging proportions of the deposited materials. Optionally, a gradient of multiple materials can be formed by depositing a gradient of one or more materials in one orientation followed by deposition of a gradient with different materials in an overlapping second orientation. For example, as shown in FIG. 9A, first gradient 900 can be deposited in a first orientation established by blocking motion 210. After a 180° orientation motion, e.g., by shuttle mechanism 403 around track 501, second gradient 901 can be deposited overlapping in orientation opposite of the first gradient. In such a case, the different materials can interact to form a composition of combinatorial materials, e.g., by annealing or melting, to provide gradients of multiple materials that change material proportions across the deposition surface.

Optionally, gradients with changing materials proportions at the surface can be prepared in one step using systems of the invention. For example, two targets with different materials can be separately illuminated during formation of a gradient. As a shutter intrudes across a deposition surface, the relative intensities of illumination for the targets can change resulting in changed material proportions at the exposed surface while earlier proportions are retained under the shutter on the blocked surfaces.

The gradient profile of a gradient deposited on a substrate can be, e.g., the change in thickness of the deposited layer along a path aligned with the direction of the associated blocking motion (gradient orientation). Gradient profiles can also be defined by the relative proportions of material constituents or the changing stoichiometry of materials deposited in a gradient. As discussed above in the Forming Gradients section, the gradient profile can reflect the velocity of the shutter with time. A controller can activate the shutter drive mechanism to provide a variety of shutter blocking motions, as desired. For example, the drive mechanism can be controlled to move the shutter in a stepped motion, constant motion, a motion that changes geometrically, logarithmically, sigmoidally, orbitally, and the like, to provide gradient profiles that change in a similar fashion.

Heaters

Systems can have heaters, e.g., to process the films of material deposited onto substrates. The heaters can be in conductive contact with a substrate to dry, bake anneal, sinter, or melt deposited materials. The heaters can be in communication with a controller for automated control of substrate temperature profiles.

Heaters can be any useful for controlling the temperature of a substrate. The heater can provide heat with, e.g., a electrically resistive heating element, an infrared lamp, microwaves, etc. The heaters can be controlled with feedback circuitry from a temperature monitor. The timing and temperature settings can be controlled by a controller, such as a computer.

Computers

Logic devices, such as computers, can monitor and control process sequences in gradient deposition systems of the invention. The computers can be programmable to reproducibly control process parameters in the system, or be reprogrammable, e.g., to modify processes for production of different gradients.

Gradient deposition systems can include, e.g., a computer system for interpreting sensor information, controlling process sequences, and adjusting system parameters. The computer can receive the information from sensors, reconfigure the system between gradient depositions and/or control system conditions in near real time. Systems in the present invention can include, e.g., a digital computer with data sets and instruction sets entered into a software system to practice the deposition methods described herein. The computer can be, e.g., a PC (Intel x86 or Pentium chip-compatible with DOS®, OS2®, WINDOWS® operating systems) a MACINTOSH®, Power PC, or SUN® work station (compatible with a LINUX or UNIX operating system) or other commercially available computer which is known to one of skill. The computer can be, e.g., a simple logic device, such as an integrated circuit or processor with memory, integrated into the weapon detector system. Software for systems feedback and control is available, or can easily be constructed by one of skill using a standard programming language such as Visualbasic, Fortran, Basic, Java, or the like. The deposition system computer can have displays and input means for a technician, such as a computer monitor and keyboard, e.g., to allow technician monitoring of a process, computer override, and process programming.

The computers can monitor process parameters and make appropriate adjustment. For example, as shown in FIG. 5, computer 506 can be in communication with optical sensor 507 to monitor the thickness of a gradient material film, with heater 500 to monitor the substrate temperature, targets 200 to monitor bias voltages, a pressure transducer to monitor chamber pressure, ion source 201 to monitor source voltage, and the like. Monitored information can be evaluated to determine if conditions are in compliance with preprogrammed limits, and appropriate responses can be made to keep the system running as designed.

The computers can communicate instructions or activate system components, e.g., through a computer interface (Optimux Controls, Coral Springs, Fla.). For example, the computer can control the timing, intensity, direction, and/or ion current from ion source 201. The computer can control: bias voltage of targets 202, injection of chamber gasses through valve 504, evacuation of gasses by vacuum pump 503, activation of a shuttle mechanism 403, rotation of a rotation assembly, blocking motions of shutter 209 mounted to a drive mechanism, and/or the like.

Computers can be particularly useful in precisely and repeatably controlling blocking motions and orientation motions. The computer can monitor the position of the shutter and/or shuttle device, e.g., from position sensors functionally mounted in the chamber, or by considering the number on “steps” taken by stepper motors associated with the drive mechanism or shuttle mechanism. The computer can command the drive mechanism to move the shutter at rates that describe mathematical functions to provide gradient profiles, as described above.

It is understood that the examples and embodiments described herein are for illustrative purposes only and that various modifications or changes in light thereof will be suggested to persons skilled in the art and are to be included within the spirit and purview of this application and scope of the appended claims.

While the foregoing invention has been described in some detail for purposes of clarity and understanding, it will be clear to one skilled in the art from a reading of this disclosure that various changes in form and detail can be made without departing from the true scope of the invention. For example, many of the techniques and apparatus described above can be used in various combinations.

All publications, patents, patent applications, and/or other documents cited in this application are incorporated by reference in their entirety for all purposes to the same extent as if each individual publication, patent, patent application, and/or other document were individually indicated to be incorporated by reference for all purposes.

What is claimed is:

1. A system for depositing gradients of one or more material onto a substrate, the system comprising:
one or more targets in electrical contact with a controllable target bias voltage;
one or more ion sources configured to selectively illuminate one or more of the targets with ions, wherein the illumination is influenced by the bias voltages of the one or more targets, thereby selectively sputtering one or more materials from the one or more targets;
a substrate comprising a deposition surface on which the sputtered material is deposited from the one or more targets; and,
a shutter device or mask capable of an orientation motion between two or more orientation coordinates around an axis normal to the deposition surface, which orientation coordinates establish orientations of mask shadows or shutter blocking motions, and thus establish orientations of two or more sputtered material gradients on the deposition surface of the substrate.

2. The system of claim 1, wherein the one or more ion sources comprise a single ion source that selectively illuminates two or more targets.

3. The system of claim 1, wherein the substrate is mounted to a rotation assembly.

4. The system of claim 3 wherein the shutter device or mask rotates with the substrate on the rotation assembly, thereby maintaining the shutter device or mask at a desired orientation coordinate while the substrate rotates.

5. The system of claim 1, wherein the shutter blocking motion is selected from the group consisting of: a constant velocity, a geometric change in velocity, a logarithmic change in velocity, a stepped motion, a sigmoidal change in velocity, and an orbital motion.

6. The system of claim 1, wherein the substrate comprises: a metal, a glass, a ceramic, a semiconductor, a polymer, carbon or silicon.

7. The system of claim 1, wherein a first gradient of deposited material is deposited with the shutter device or mask at a first orientation coordinate, and a second gradient of deposited material is deposited with the shutter device or mask at a second orientation coordinate.

8. The system of claim 7, wherein the first gradient of deposited material is sputtered from a first target and the second gradient of deposited material is sputtered from a second target.

9. The system of claim 1, wherein the one or more targets comprise one or more materials selected from the group consisting of: Aluminum, Antimony, Barium, Bismuth, Boron, Cadmium, Calcium, Carbon, Cerium, Chromium, Cobalt, Copper, Dysprosium, Erbium, Europium, Gadolinium, Germanium, Gold, Hafnium, Holmium, Indium, Iridium, Iron, Lanthanum, Lead, Lithium, Lutetium, Niobate, Magnesium, Manganese, Molybdenum, Neodymium, Nickel, Niobium, Palladium, Permalloy, Platinum, Polonium, Praseodymium, Rhenium, Rhodium, Ruthenium, Samarium, Scandium, Selenium, Silicon, Silver, Strontium, Tantalum, Tellurium, Terbium, Thallium, Thulium, Tin, Titanium, Tungsten, Vanadium, Ytterbium, Yttrium, Zinc, Zirconium, and oxidized forms thereof.

10. The system of claim 1, further comprising a heating unit to bake, dry, anneal, sinter or melt the deposited material.

11. The system of claim 1, further comprising a computer interfaced with the system to control one or more of the following: the target bias voltage, an ion source current, a substrate rotation, a deposited layer thickness, the orientation coordinate of the shutter device or mask, the blocking motion of the shutter, a gas flow, a chamber gas pressure, and heating of the substrate.

12. A system for depositing gradients of one or more materials onto a substrate, the system comprising:
one or more targets;
one or more ion sources directed to illuminate one or more of the targets with ions, thereby sputtering one or more materials from the illuminated targets;
a rotatable substrate comprising a deposition surface on which the sputtered material is deposited; and,
one or more masks or shutters mounted to rotate with the substrate, thereby remaining at an orientation coordinate relative to the deposition surface, so that:
an orientation of a shutter blocking motion across and relative to the deposition surface is maintained when the substrate spins; or,
an orientation of a mask shadow on the deposition surface is maintained when the substrate spins;
whereby a gradient of one or more deposited materials is established in an orientation according to the orientation of the mask shadow on the deposition surface or according to the shutter blocking motion relative to the deposition surface while the substrate spins.

13. The system of claim 12, wherein a single ion source selectively illuminates two or more targets.

14. The system of claim 12, wherein the one or more targets comprise one or more materials selected from the group consisting of: Aluminum, Antimony, Barium, Bismuth, Boron, Cadmium, Calcium, Carbon, Cerium, Chromium, Cobalt, Copper, Dysprosium, Erbium, Europium, Gadolinium, Germanium, Gold, Hafnium, Holmium, Indium, Iridium, Iron, Lanthanum, Lead, Lithium, Lutetium, Niobate, Magnesium, Manganese, Molybdenum, Neodymium, Nickel, Niobium, Palladium, Permalloy, Platinum, Polonium, Praseodymium, Rhenium, Rhodium, Ruthenium, Samarium, Scandium, Selenium, Silicon, Silver, Strontium, Tantalum, Tellurium, Terbium, Thallium, Thulium, Tin, Titanium, Tungsten, Vanadium, Ytterbium, Yttrium, Zinc, Zirconium, and oxidized forms thereof.

15. The system of claim 12, wherein the substrate comprises: a metal, a glass, a ceramic, a semiconductor, a polymer, carbon or silicon.

16. The system of claim 12, wherein the mask or shutter is mounted to a common rotation assembly with the substrate.

17. The system of claim 12, wherein the shutter blocking motion is selected from the group consisting of: a constant velocity, a geometric change in velocity, a logarithmic change in velocity, a sigmoidal change in velocity, a stepped motion, and an orbital motion.

18. The system of claim 12, wherein a first gradient of deposited material is deposited with the mask or shutter device at a first orientation coordinate, and a second gradient of deposited material is deposited with the mask or shutter device at a second orientation coordinate.

19. The system of claim 18, wherein the first gradient of deposited material is sputtered from a first target and the second gradient of deposited material is sputtered from a second target.

20. The system of claim 12, further comprising a heating unit to bake, dry, anneal, sinter or melt the deposited material.

21. The system of claim 12, further comprising a computer interfaced with the system to control one or more parameter selected from the group consisting of: a target bias, an ion source current, the substrate rotation, a deposited layer thickness, the orientation coordinate of the one or more shutter devices, the orientation coordinate of the one or more masks, the blocking motion of the shutter, a gas flow, a chamber gas pressure, and heating of the substrate.

22. A system for depositing gradients of one or more materials onto a substrate, the system comprising:
one or more targets;
one or more ion sources directed to illuminate one or more of the targets with ions, thereby sputtering one or more materials from one or more of the targets;
a substrate comprising a deposition surface on which the one or more sputtered materials is deposited; and,
a single shutter device capable of an orientation motion between two or more orientation coordinates around an axis normal to the deposition surface, which orientation motion establishes orientations for blocking motions of a shutter across the deposition surface,
whereby, with the shutter device at a first orientation coordinate, the blocking motion of the shutter across the deposition surface during material sputtering establishes a first gradient of one or more deposited materials on the deposition surface in a first orientation;
and, wherein movement of the shutter device to a second orientation coordinate and blocking motion of the shutter across the deposition surface during material sputtering establishes a second gradient of one or more deposited materials on the substrate in a second orientation.

23. The system of claim 22, further comprising independently controllable target bias voltages in contact with each of two or more of the targets.

24. The system of claim 22, wherein the one or more ion sources comprises a single ion source that can illuminate two or more targets sequentially or at once.

25. The system of claim 22, wherein the substrate is mounted to a rotation assembly.

26. The system of claim 25, wherein the shutter device rotates with the substrate on the rotation assembly, thereby retaining the orientation coordinates of the shutter device while the substrate rotates.

27. The system of claim 22, wherein the shutter blocking motion is selected from the group consisting of: a constant velocity, a geometric change in velocity, stepped motion, a logarithmic change in velocity, a sigmoidal change in velocity, and an orbital motion.

28. The system of claim 22, further comprising one or more masks positioned between the one or more targets and the deposition surface.

29. The system of claim 22, wherein the first gradient of deposited material is sputtered from a first target and the second gradient of deposited material is sputtered from a second target.

30. The system of claim 22 wherein the one or more targets comprise one or more materials selected from the group consisting of: Aluminum, Antimony, Barium, Bismuth, Boron, Cadmium, Calcium, Carbon, Cerium, Chromium, Cobalt, Copper, Dysprosium, Erbium, Europium, Gadolinium, Germanium, Gold, Hafnium, Holmium, Indium, Iridium, Iron, Lanthanum, Lead, Lithium, Lutetium, Niobate, Magnesium, Manganese, Molybdenum, Neodymium, Nickel, Niobium, Palladium, Permalloy, Platinum, Polonium, Praseodymium, Rhenium, Rhodium, Ruthenium, Samarium, Scandium, Selenium, Silicon, Silver, Strontium, Tantalum, Tellurium, Terbium, Thallium, Thulium, Tin, Titanium, Tungsten, Vanadium, Ytterbium, Yttrium, Zinc, Zirconium, and oxidized forms thereof.

31. The system of claim 22, further comprising a heating unit to bake, dry, anneal, sinter, or melt the deposited material.

32. The system of claim 22, further comprising a detector selected from the group consisting of: a spectroscope, a magnetometer, a microscope, voltage meter, an ohm meter, and a fluorometer.

33. The system of claim 22, further comprising a computer interfaced with the system to control one or more of the following: a target bias voltage, an ion source current, a substrate rotation, a deposited layer thickness, the orientation motion of the one or more shutter devices, the blocking motion of the one or more shutters, a gas flow, a chamber gas pressure, and heating of the substrate.

34. A method of depositing gradients of one or more materials onto a substrate, the method comprising:
controlling target bias voltages in contact with one or more targets;
illuminating one or more first targets with ions from an ion source to sputter one or more first materials from the one or more of the first targets, wherein said illuminating is influenced by the bias voltages in contact with the one or more targets;
blocking a portion of the one or more sputtered materials from deposition onto a substrate deposition surface with a mask or shutter device at a first orientation coordinate around an axis normal to the deposition surface, thereby depositing a first gradient of the one or more materials onto the deposition surface in a first orientation;
changing the orientation coordinate of the mask or shutter device to a second orientation coordinate:
by rotating the substrate; or,
by moving the mask or shutter device in an orientation motion;
illuminating one or more second targets to sputter one or more second materials; and,
blocking deposition of a portion of the one or more second sputtered materials onto the substrate deposition surface with the mask or shutter device at the second orientation coordinate, thereby depositing a second gradient of the one or more second materials onto the deposition surface in a second orientation.

35. The method of claim 34, wherein said illuminating comprises independently controlling target bias voltages in contact with two or more of the targets.

36. The method of claim 35, further comprising controlling a proportion of two or more materials sputtered from the two or more targets by independently controlling the amplitude of the bias voltages in contact with the two or more targets.

37. The method of claim 34, wherein the movement of the shutter blocking motion is selected from the group consisting of: a constant velocity, a geometric change in velocity, a logarithmic change in velocity, a stepped motion, a sigmoidal change in velocity, and an orbital motion.

38. The method of claim 34, wherein the second orientation coordinate of the mask or shutter device is 180° from the first orientation coordinate.

39. The method of claim 34, further comprising:
moving the shutter device to a third orientation coordinate;
moving the shutter in a third blocking motion; and,
depositing a third gradient of one or more third sputtered materials in a third orientation.

40. The method of claim 34, further comprising moving the shutter device to three or more orientation coordinates to establish orientations for three or more gradients of material.

41. The method of claim 34, further comprising spinning the substrate during deposition of the first or second gradient.

42. The method of claim 41, further comprising retaining the orientation coordinates of the mask or shutter device while the substrate spins.

43. The method of claim 34, further comprising overlapping the gradients on the deposition surface.

44. The method of claim 34, further comprising heating the substrate to fuse the first gradient and second gradient materials.

45. The method of claim 34, further comprising detecting characteristics at locations on the deposition surface using methods selected from the group consisting of: spectroscopy, detecting electromagnetism, microscopy, detecting a voltage, detecting a voltage in response to a pressure, detecting a voltage in response to light exposure, detecting electrical resistance or fluoroscopy.

46. A combinatorial library produced according to the method of claim 34.

47. A method of depositing gradients of one or more materials onto a substrate, the method comprising:
illuminating one or more first targets with ions from one or more ion sources, thereby sputtering one or more materials from the one or more first targets;
moving a shutter in a first blocking motion across a deposition surface of the substrate, which shutter mounted to a shutter device located at a first orientation coordinate around an axis normal to the deposition surface;
depositing a first gradient of the one or more first sputtered materials in an orientation determined by the first blocking motion and the first orientation coordinate;
moving the shutter device in an orientation motion to a second orientation coordinate around the normal axis;
illuminating one or more second targets with ions from the one or more ion sources, thereby sputtering one or more second materials from the one or more second targets;
moving the shutter in a second blocking motion across the deposition surface of the substrate; and,
depositing a second gradient of the second sputtered material in an orientation determined by the second blocking motion and the second orientation coordinate.

48. The method of claim 47, wherein said illuminating comprises: controlling bias voltages in contact with the one or more targets.

49. The method of claim 48, further comprising controlling a proportion of two or more materials sputtered from two or more targets by independently controlling the bias voltage in contact with two or more of the targets.

50. The method of claim 47, wherein the movement of the shutter blocking motion is selected from the group consisting of: a constant velocity, a geometric change in velocity, a logarithmic change in velocity, a stepped motion, a sigmoidal change in velocity, and an orbital motion.

51. The method of claim 47, wherein the second orientation coordinate of the shutter device is about 180° from the first orientation coordinate.

52. The method of claim 47, further comprising:
moving the shutter device to a third orientation coordinate;
moving the shutter in a third blocking motion; and,
depositing a third gradient of sputtered material in a third orientation.

53. The method of claim 52, wherein the second orientation coordinate of the shutter device is about 120° from the first orientation coordinate, and wherein the third orientation coordinate is about 240° from the first orientation coordinate.

54. The method of claim 47, further comprising moving the shutter device to three or more orientation coordinates to establish gradient orientations for three of more gradients of material.

55. The method of claim 47, further comprising spinning the substrate during deposition of the first or second gradient.

56. The method of claim 55, further comprising retaining the orientation coordinates of the shutter device while the substrate spins.

57. The method of claim 47, further comprising positioning one or more masks between the one or more targets and the deposition surface.

58. The method of claim 47, further comprising overlapping the gradients on the deposition surface.

59. The method of claim 47, further comprising heating the substrate to a temperature of about 500° C. or more.

60. The method of claim 47, further comprising detecting characteristics at locations on the deposition surface using methods selected from the group consisting of: spectroscopy, detecting electromagnetism, microscopy, detecting a voltage, detecting a voltage in response to a pressure, detecting a voltage in response to light exposure, detecting electrical resistance, and fluoroscopy.

61. A combinatorial library produced according to the method of claim 47.

62. A method for depositing gradients of one or more materials onto a substrate, the method comprising:
illuminating one or more targets with ions from one or more ion sources, thereby sputtering one or more materials from the one or more targets;
spinning a substrate along with a shutter device comprising a shutter so that the shutter device is maintained at an orientation coordinate around an axis normal to a deposition surface of the substrate;
moving the shutter in a blocking motion across the deposition surface of the substrate; and,
depositing the one or more sputtered materials onto the deposition surface;
thereby depositing a first gradient of the one or more sputtered materials in an orientation established according to the blocking motion of the shutter relative to the deposition surface.

63. The method of claim 62, wherein said illuminating comprises controlling target bias voltages in contact with the one or more targets.

64. The method of claim 63, further comprising controlling a proportion of material sputtered from two or more targets by independently controlling an amplitudes of bias voltages in contact with the two or more of the targets.

65. The method of claim 62, wherein the movement of the shutter blocking motion is selected from the group consisting of: a constant velocity, a geometric change in velocity, a logarithmic change in velocity, a stepped motion, a sigmoidal change in velocity, and an orbital motion.

66. The method of claim 62, further comprising:
moving the shutter device to a different orientation coordinate;
moving the shutter in the blocking motion; and,
depositing a second gradient of one or more sputtered materials in a different orientation on the deposition surface.

67. The method of claim 66, further comprising illuminating one or more different targets during the deposition of the second gradient than were illuminated during deposition of the first gradient.

68. The method of claim 67, further comprising overlapping the gradients on the deposition surface.

69. The method of claim 62, further comprising moving the shutter device to three or more different orientation coordinates to establish orientations of three or more gradients of material.

70. The method of claim 62, further comprising detecting characteristics at locations on the deposition surface using methods selected from the group consisting of: spectroscopy, detecting electromagnetism, microscopy, detecting a voltage, detecting a voltage in response to a pressure, detecting a voltage in response to light exposure, detecting electrical resistance or fluoroscopy.

71. The method of claim 62, further comprising heating the substrate.

72. A combinatorial library produced according to the method of claim 62.

73. A method for making a gradient on a substrate, the method comprising:
sputtering materials from two or more targets in proportions that change with time; and
moving a shutter across a substrate to progressively block deposition of the sputtered materials;
thereby forming a gradient of materials which change in proportion across the substrate.

74. The method of claim 73, wherein said sputtering comprises illuminating two targets with two ion sources each having independently controllable ion currents.

75. The method of claim 73, wherein said sputtering comprises independent control of target material sputtering by independently controlling target bias voltages for each of the two or more targets.

76. The method of claim 75, wherein said sputtering further comprises illuminating f two targets with one ion source.

77. The method of claim 73, wherein said sputtering further comprises switching illumination from one target to another while the shutter is moving.

78. The method of claim 62, further comprising detecting characteristics at locations on the gradient using methods selected from the group consisting of: spectroscopy, detecting electromagnetism, microscopy, detecting a voltage, detecting a voltage in response to a pressure, detecting a voltage in response to light exposure, detecting electrical resistance or fluoroscopy.
